(19) United States
(12) Patent Application Publication
(10) Pub. No.: US 2017/0059669 A1
(43) Pub. Date: Mar. 2, 2017

(54) MAGNETIC FIELD ENHANCING BACKING PLATE FOR MRAM WAFER TESTING

(71) Applicant: QUALCOMM Incorporated, San Diego, CA (US)

(72) Inventors: Jimmy Kan, San Diego, CA (US); Matthias Georg Gottwald, Leuven (BE); Chando Park, San Diego, CA (US); Seung Hyuk Kang, San Diego, CA (US)

(21) Appl. No.: 14/836,860

(22) Filed: Aug. 26, 2015

(51) Int. Cl. G01R 33/12; G11C 11/16; G11C 29/04

(52) U.S. Cl. CPC G01R 33/1207; G11C 29/04; G11C 11/16

(57) ABSTRACT

A method and apparatus for testing a magnetic memory device is provided. The method begins when a magnetic field enhancing backing plate is installed in the test fixture. The magnetic field enhancing backing plate may be installed in the wafer chuck of a wafer testing probe station. The magnetic memory device is installed in the test fixture and a magnetic field is applied to the magnetic memory device. The magnetic field may be applied in-plane or perpendicular to the magnetic memory device. The performance of the magnetic memory device may be determined based on the magnetic field applied to the device. The apparatus includes a magnetic field enhancing backing plate adapted to fit a test fixture, possibly in the wafer chuck. The magnetic field enhancing backing plate is fabricated of high permeability magnetic materials, such as low carbon steel, with a thickness based on the magnetic field used in testing.

### FIELD

The present disclosure relates generally to testing electronic devices, and more particularly, to a magnetic field enhancing backing plate for testing magnetoresistive random access memory (MRAM) devices.

### BACKGROUND

Electronic devices of all types have become an important part of everyday life. Increasingly, users rely on mobile phones, computers, tablets and similar devices for communication, work, and entertainment. As the use and capability of electronic devices have increased, the memories used in those devices have evolved to increase storage and improve performance. Over time memories have evolved into highly complex devices that require considerable testing to ensure the once installed in the end use device, they perform as desired.

Most devices contain a fundamental memory that stores a plethora of instructions and retain values and commend strings used in performing multiple functions. This increased need to store complex values and instructions has led to the development of magnetoresistive random access memories. (MRAM). MRAM devices may be used as the main or cache memory for many devices because of the many benefits they provide such as non-volatility, high speed, and low power consumption. MRAM provides storage through the use of magnetic tunnel junctions (MTJ). Perpendicular magnetic tunnel junctions are used as the fundamental memory element in high performance spin transfer torque MRAM devices.

Testing these memory devices poses a number of significant challenges. One of the testing challenges is that MRAM devices must be tested with an electromagnet. Typically testing is done on wafers, before individual devices are separated and chips are packaged. A 300 mm probe station is used to test the wafers. A dipole magnet cannot be used with a wafer chuck on a 300 mm probe station, as only one pole of the dipole magnet may be used, which provides substantially lower and less uniform magnetic field. Custom probe cards with integrated magnets have also been used, however, the cost is increased, and any change to the device to be tested necessitates redesign of the probe card.

Improved MRAM devices require higher magnetic fields for testing, and the magnetic fields required to switch the device is very high. Conventional electromagnets will not suffice, as the magnetic field will be surpassed by the coercive field of the MRAM device. Projection field magnets are one of the options for wafer-level magnetic characterization of MRAM. Modern perpendicular magnetic tunnel junction devices have improved magnetic coercivity and require large magnetic fields, on the order of more than 3 kOe to characterize. Most 300 mm probe stations used in testing conventional memories (such as SRAM, DRAM, flash) do not have any magnetic field capability. Retrofitting a magnet to a conventional 300 mm probe station is not effective, as most magnets available cannot produce large enough or uniform magnetic fields. Using available stations with a large magnetic field still may not solve the problem as stations with large magnetic fields have poor field uniformity and typically can only support smaller wafers or coupon wafers, making testing time consuming for larger wafers and lots.

There is a need in the art for a magnetic field enhancing backing plate for MRAM wafer testing to allow testing using existing electromagnetic testing apparatus for both in-plane and perpendicular MRAM testing.

### SUMMARY

Embodiments described herein provide a method for testing a memory device. The memory device may be a MRAM device, or other device incorporating magnetic storage. The method begins when a magnetic field enhancing backing plate is installed in the test fixture. The magnetic field enhancing backing plate may be installed in the wafer chuck of a wafer testing probe station. The magnetic memory device is then installed in the test fixture and a magnetic field is applied to the magnetic memory device. The magnetic field may be applied in-plane or perpendicular to the magnetic memory device. The performance of the magnetic memory device may be determined based on the magnetic field applied to the device.

A further embodiment provides an apparatus for testing a memory device. The apparatus includes a magnetic field enhancing backing plate that is adapted to fit a test fixture. Typically the magnetic field enhancing backing plate is adapted to fit a wafer chuck of a wafer testing or probe station. The magnetic field enhancing backing plate is fabricated of higher permeability magnetic materials, such as low carbon steel. The thickness of the magnetic field enhancing backing plate may be adapted depending on the MRAM or magnetic device being tested and the level of magnetic field needed for thorough testing.

A still further embodiment provides an apparatus for testing a memory device. The apparatus includes: means for installing a magnetic field enhancing backing plate in a test fixture; means for installing a magnetic memory device in the test fixture; means for applying a magnetic field to the magnetic memory device; and means for determining performance of the magnetic memory device based on the applied magnetic field.

### BRIEF DESCRIPTION OF THE DRAWINGS

FIG. 1 illustrates a typical 300 mm testing apparatus with an electromagnet, in accordance with embodiments of the disclosure.

FIG. 2 shows a sample field strength profile of an electromagnet used for testing MRAM devices, in accordance with embodiments of the disclosure.

FIG. 3 is a finite element model of two pole pieces, in accordance with embodiments of the disclosure.

FIG. 4 illustrates a cross sectional view of the magnetic field, in accordance with embodiments of the disclosure.

FIG. 5 depicts the magnetic field produced when a magnetic field enhancing backing plate is used, in accordance with embodiments of the disclosure.

FIG. 6 shows the magnetic field produced when a magnetic field enhancing backing plate is used compared to no backing, in accordance with embodiments of the disclosure.

FIG. 7 illustrates the difference in magnetic field when a magnetic field enhancing backing plate is used and when no magnetic field enhancing backing plate is used versus the magnitude of the electrical current supplied to the electromagnet, in accordance with embodiments of the disclosure.

FIG. 8 is a flowchart of a method of testing an MRAM device using a magnetic field enhancing backing plate, in accordance with embodiments of the disclosure.

### DETAILED DESCRIPTION

The detailed description set forth below in connection with the appended drawings is intended as a description of exemplary embodiments of the present invention and is not intended to represent the only embodiments in which the present invention can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the invention. It will be apparent to those skilled in the art that the exemplary embodiments of the invention may be practiced without these specific details. In some instances, well-known structures and devices are shown in block diagram form in order to avoid obscuring the novelty of the exemplary embodiments presented herein.

As used in this application, the terms “component,” “module,” “system,” and the like are intended to refer to a computer-related entity, either hardware, firmware, a combination of hardware and software, software, or software in execution. For example, a component may be, but is not limited to being, a process running on a processor, an integrated circuit, a processor, an object, an executable, a thread of execution, a program, and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets (e.g., data from one component interacting with another component in a local system, distributed system, and/or across a network, such as the Internet, with other systems by way of the signal).

Furthermore, various aspects are described herein in connection with an access terminal and/or an access point. An access terminal may refer to a device providing voice and/or data connectivity to a user. An access wireless terminal may be connected to a computing device such as a laptop computer or desktop computer, or it may be a self-contained device such as a cellular telephone. An access terminal can also be called a system, a subscriber unit, a subscriber station, mobile station, mobile, remote station, remote terminal, a wireless access point, wireless terminal, user terminal, user agent, user device, or user equipment. A wireless terminal may be a subscriber station, wireless device, cellular telephone, PCS telephone, cordless telephone, a Session Initiation Protocol (SIP) phone, a wireless local loop (WLL) station, a personal digital assistant (PDA), a handheld device having wireless connection capability, or other processing device connected to a wireless modem. An access point, otherwise referred to as a base station or base station controller (BSC), may refer to a device in an access network that communicates over the air-interface, through one or more sectors, with wireless terminals. The access point may act as a router between the wireless terminal and the rest of the access network, which may include an Internet Protocol (IP) network, by converting received air-interface frames to IP packets. The access point also coordinates management of attributes for the air interface.

Moreover, various aspects or features described herein may be implemented as a method, apparatus, or article of manufacture using standard programming and/or engineering techniques. The term “article of manufacture” as used herein is intended to encompass a computer program accessible from any computer-readable device, carrier, or media. For example, computer readable media can include but are not limited to magnetic storage devices (e.g., hard disk, floppy disk, magnetic strips . . . ), optical disks (e.g., compact disk (CD), digital versatile disk (DVD) . . . ), smart cards, and flash memory devices (e.g., card, stick, key drive . . . ), and integrated circuits such as read-only memories, programmable read-only memories, and electrically erasable programmable read-only memories.

Various aspects will be presented in terms of systems that may include a number of devices, components, modules, and the like. It is to be understood and appreciated that the various systems may include additional devices, components, modules, etc. and/or may not include all of the devices, components, modules etc. discussed in connection with the figures. A combination of these approaches may also be used.

Other aspects, as well as features and advantages of various aspects, of the present invention will become apparent to those of skill in the art through consideration of the ensuring description, the accompanying drawings and the appended claims.

MRAM devices are a non-volatile random access memory technology. Unlike convention random access memory (RAM) chips, data in MRAM devices are stored in magnetic storage elements and not as electric charge or current flows. The elements are formed from two ferromagnetic layers. Each ferromagnetic layer can hold a magnetization, separated by a thin insulating layer. One of the two layers is a permanent magnet set to a particular polarity (reference layer). The magnetization of the other layer (free layer) may be changed relative to the reference layer by application of electrical current through the device or by external magnetic field. This configuration is known as a magnetic tunnel junction and is the elementary structure for an MRAM bit. A memory device is comprised of an array of such cells.

Reading the MRAM may be done by measuring the electrical resistance of the cell. Typically, a particular cell is selected by powering an associated transistor that switches current from a supply line through the cell to ground. Due to the tunneling magnetoresistance (TMR) effect, the electrical resistance of the cell changes depending on the relative orientations of the magnetizations between RL and FL. By measuring the resulting current, the resistance inside any particular cell can be determined, and from this the magnetization polarity of the free layer. If the two layers have the same magnetic orientation, the resistance is low, while if the two layers have opposing magnetic orientations, the resistance is higher.

Data is written to the cells using a variety of methods. In the case of STT-MRAM, electrical current passing through the device becomes spin-polarized and causes reorientation of the free layer magnetic polarity. The orientation can be reverted by reversing the direction of the current.

MRAM devices rely on magnetic tunnel junctions for storing data. Tunnel magnetoresistance is a magnetoresistive effect that occurs in a magnetic tunnel junction (MTJ). A magnetic tunnel junction consists of two ferromagnets separated by a thin insulator. If the insulating layer is thin enough (on the order of a few nanometers), electrons can tunnel from one ferromagnet into the other. This tunneling is a quantum mechanical phenomenon. Magnetic tunnel junctions are manufactured using thin-film technology.

The direction of the two magnetizations of the ferromagnetic films may be switched individually by an external magnetic field or by passing an electrical current through the device. If the magnetizations are in a parallel orientation it is more likely that electrons will tunnel through the insulating film. If the magnetizations are in an opposite or anti-parallel orientation it is less likely that electrons will tunnel through the insulating film. As a result, such a junction may be switched between two states of electrical resistance, one with low resistance, and one with very high resistance.

Magnetic tunnel junctions rely on spin transfer torque. The effect of spin transfer torque appears when there is a tunneling barrier sandwiched between a set of two ferromagnetic electrodes such that there is freely rotatable magnetization on one electrode, while the other electrode (which has a fixed magnetization) acts as a spin polarizer.

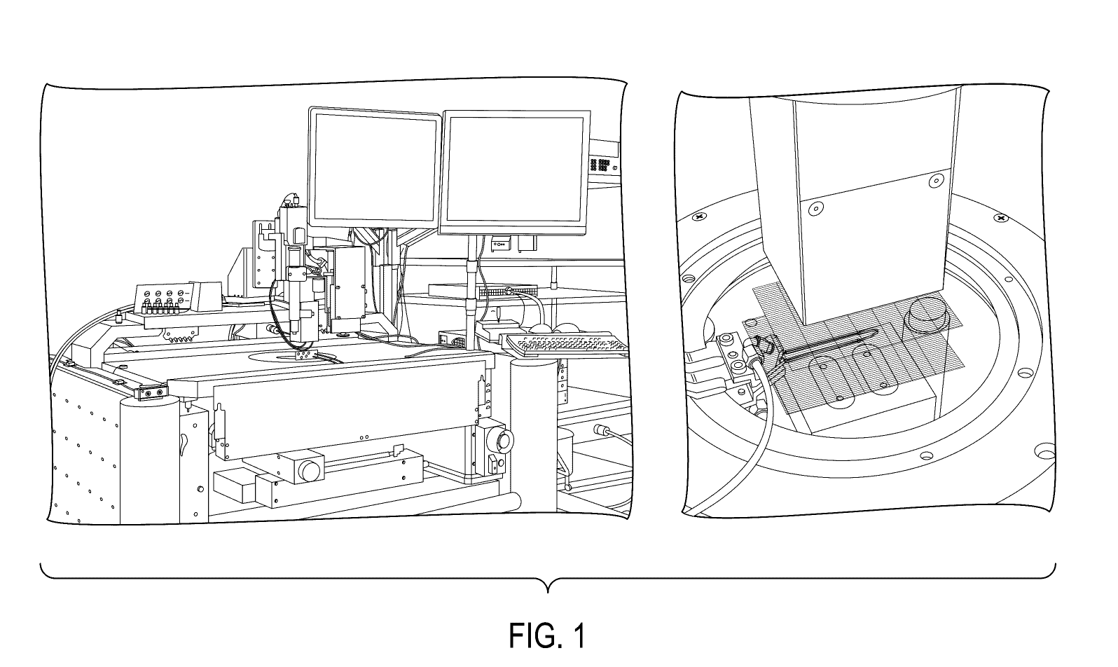

FIG. 1 illustrates a 300 mm probe station. Such probe stations do not include magnetic field capability. Retrofitting magnets do not produce a large enough magnetic field, while, as noted above, stations that do have magnetic capability are not able to handle the larger wafers needed for production runs. As MRAM devices have developed and advanced, the magnetic fields needed for testing have increased. Currently the magnetic fields needed to switch the MRAM device is very high, and may be on the order of 3 kOe. Conventional electromagnets will not work, as the magnetic fields produced are not high enough. Also shown in FIG. 1 is an electromagnet fitted to a conventional 300 mm probe station. The device wafer is also shown is relation to the electromagnet.

MRAM devices have changed from an “in-plane” magnetic orientation, to a “perpendicular” alignment. In these MRAM devices, the magnetic orientation is perpendicular to the wafer. This configuration produces an improved field tolerance, higher retention, lower switching power, and improved scalability. As MRAM devices continue to develop, it may become necessary to test with larger magnetic fields and better field uniformity. 400 mm size wafers may also be used as the devices gain in complexity. These future devices may require testing with additional magnetic fields.

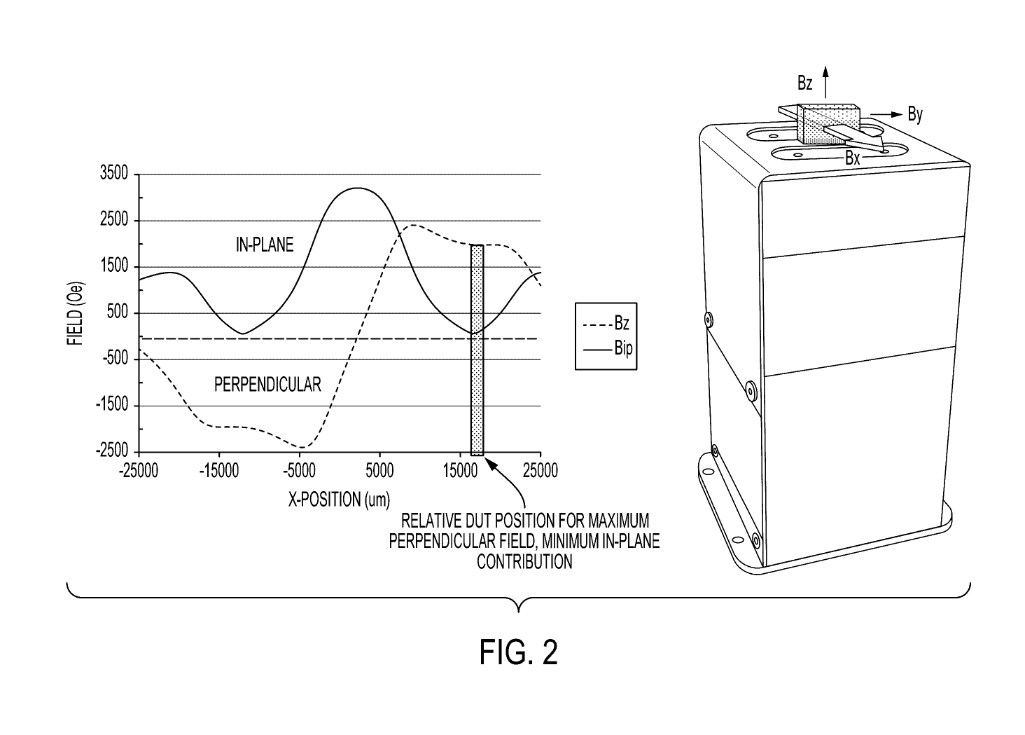

FIG. 2 provides an example profile of an existing electromagnet. The electromagnet is also shown in FIG. 2. The magnetic fields for in-plane and perpendicular configurations are shown in the graph. FIG. 2 also includes the relative position of the device under test (DUT) for maximum perpendicular magnetic field with a minimum in-plane contribution. It is at this point where testing of the MRAM should take place. Using larger magnets requires larger drive currents and substantial magnet redesign in order to tolerate the heat load generated from such large drive currents.

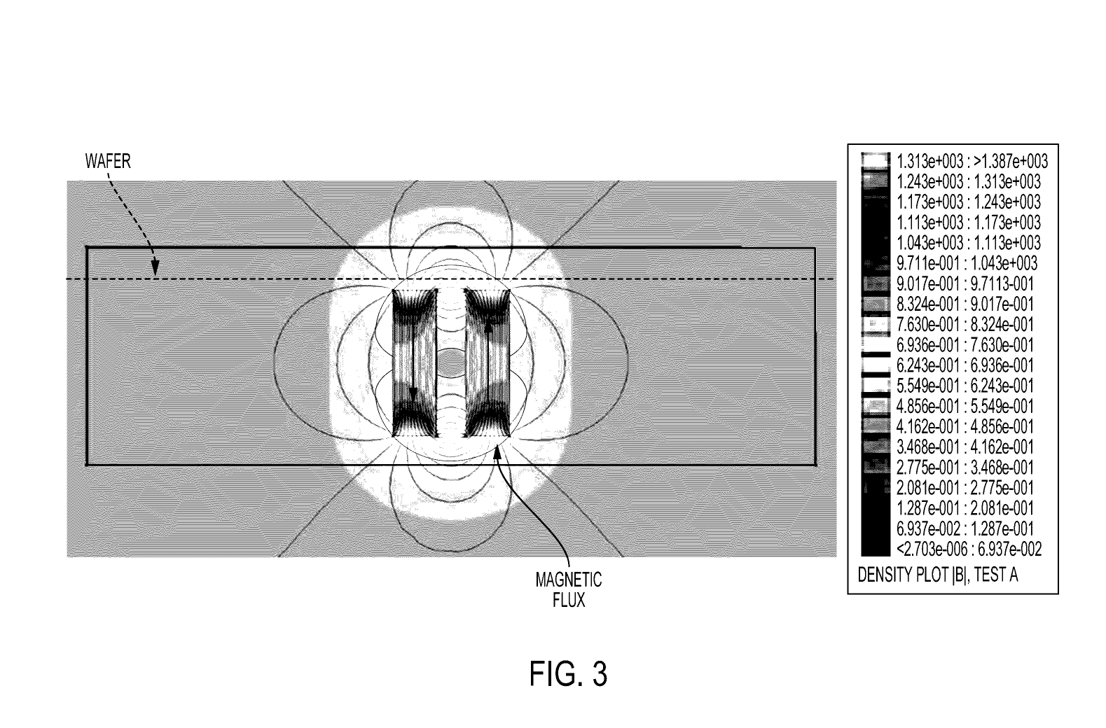

FIG. 3 depicts finite element modeling of two pole pieces of an electromagnet used in testing an MRAM device. There is magnetic field leakage due to the inefficient inductance path to close the magnetic flux. Most of the magnetic flux leaks into the open air around the device being tested, and as a result, is wasted.

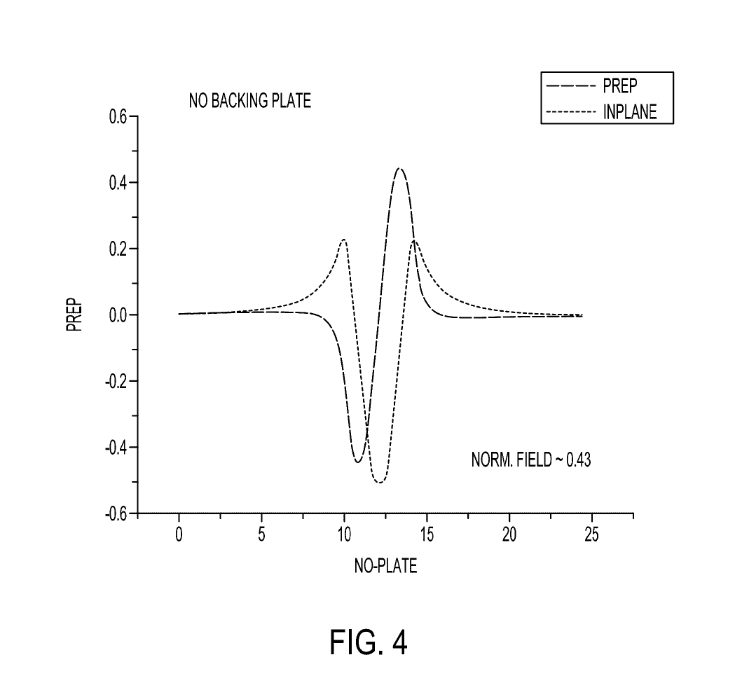

FIG. 4 provides a cross-sectional view of the magnetic field with no backing plate. This shows the loss in magnetic field, with the magnetic field dissipating into the air around the MRAM device.

An embodiment provides a magnetic field enhancing backing plate that is added to the 300 mm wafer checks. This magnetic field enhancing backing plate may be added to the surface of the chuck on the probe station. In an alternate embodiment, the magnetic material may be added to the surface of the chuck. The magnetic field enhancing backing plate is formed from a high magnetic permeability material that is placed near the magnetic poles. This high magnetic permeability material may reduce the waste of the magnetic field by providing a high inductance magnetic flux closure path near the DUT.

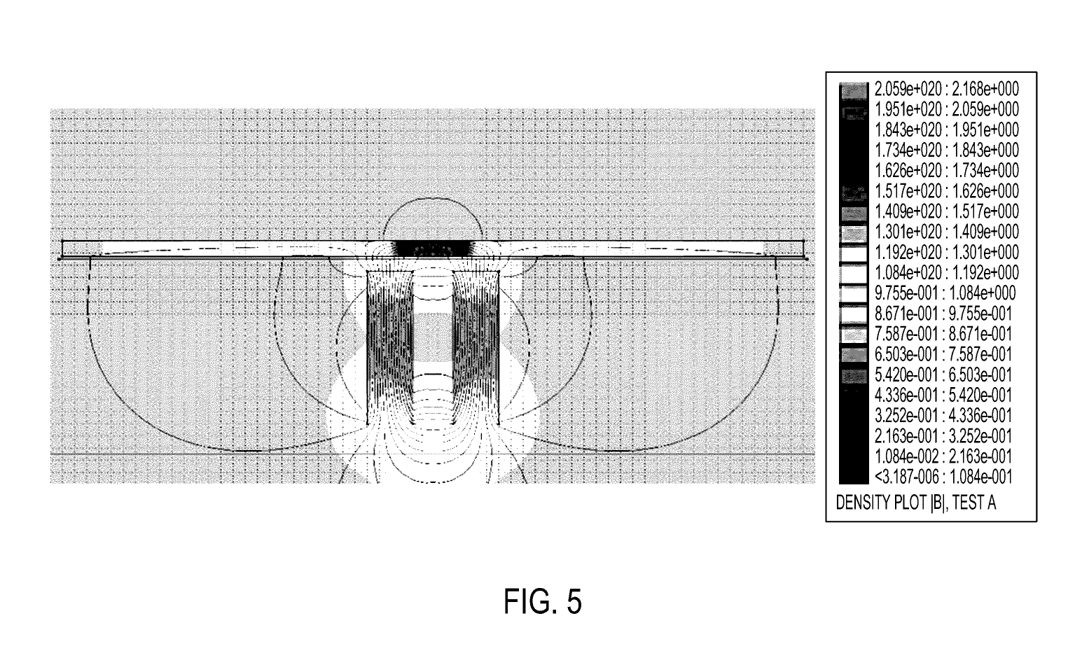

FIG. 5 depicts MRAM device testing using a magnetic field enhancing backing plate. In FIG. 5 improvement of the magnetic field experienced by the DUT is estimated to be 45% when a backing plate of 1006 low carbon steel, 1 mm thick is used. The magnetic field in FIG. 5 is improved over that shown in FIG. 3 as both poles of the magnet are directing a magnetic field to the DUT. While 1006 low carbon steel is used to produce the magnetic field illustrated in FIG. 5, the embodiments described herein are not limited to this material selection. The magnetic enhancing material may be selected from the wide variety of materials which enhance a magnetic field and may be selected to test a particular device having properties different from the typical MRAM described herein.

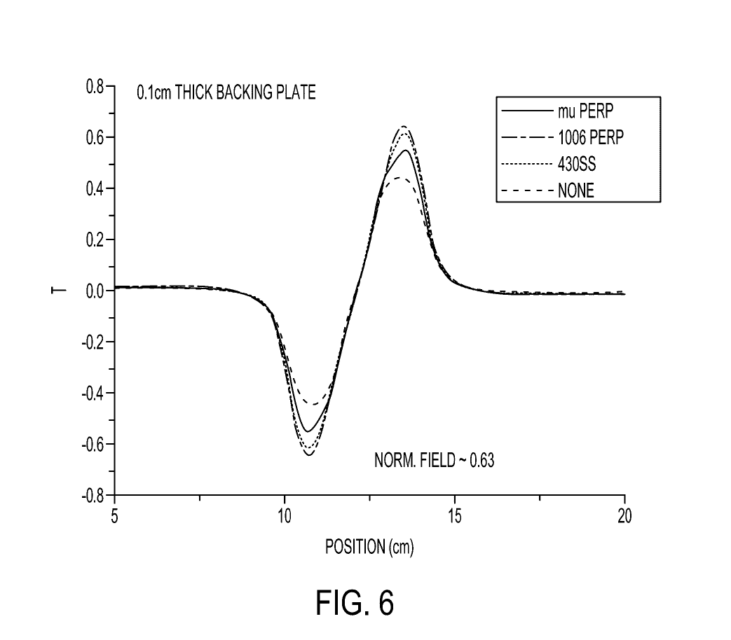

FIG. 6 shows the improvement in the cross-section of the magnetic field produced when the magnetic field enhancing backing plate is used.

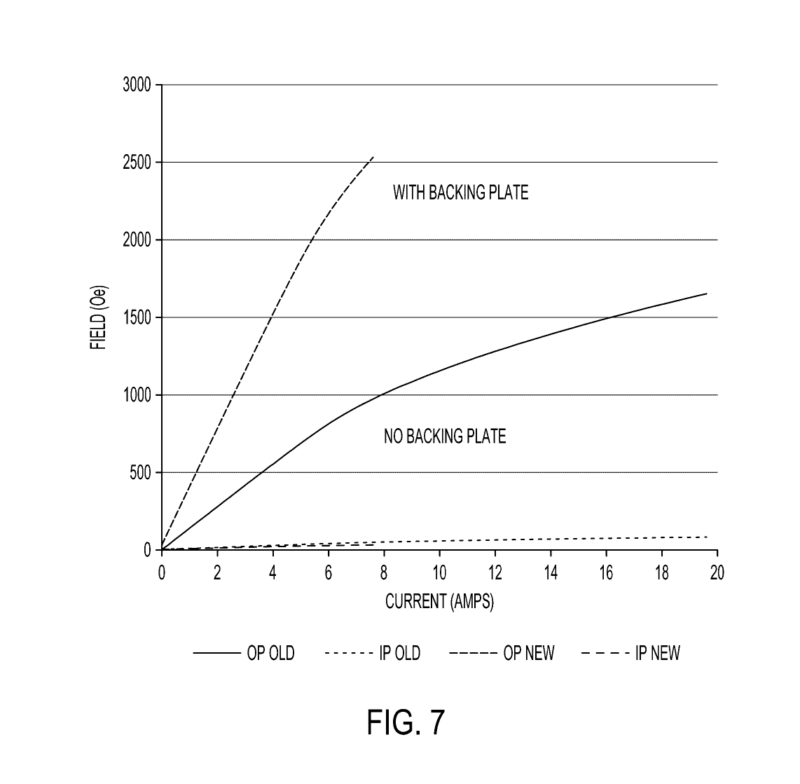

FIG. 7 shows the improvement in magnetic field due to the magnetic field enhancing backing plate. A 5 mm thick fabricated backing plate was installed on a 300 mm probe station. The magnetic field enhancing backing plate was attached to the surface of the wafer chuck. The magnetic field enhancing backing plate may be adapted to fit to a variety of probe stations and may be used on probe stations of various sizes. The embodiments described herein are not limited to the example sizes and probe stations discussed in the application. As the graph in FIG. 7 illustrates measurements of the magnetic field were made with and without the magnetic field enhancing backing plate. The magnetic field was increased up to 2.5 times at the same magnet drive current by the addition of the magnetic field enhancing backing plate. In addition, magnetic field uniformity was increased, due to the suppression of the in-plane magnetic field.

The embodiments described herein provide the higher magnetic fields required for wafer level testing of perpendicular magnetic tunnel junction MRAM devices. The magnetic field enhancing backing plate provides a mechanism to achieve a higher magnetic field without merely increasing the excitation current. Using the magnetic field enhancing backing plate utilizes the fundamental properties of higher permeability magnetic materials to minimize waste of magnetic flux. This allows testing to be conducted in a more modular fashion, as the distance to the DUT may be maintained, and not decreased. The magnetic field enhancing backing plate may also be used for MRAM final test and field setting, where it may be used to ensure that all the magnetic devices on the chip are lined up in the proper orientation.

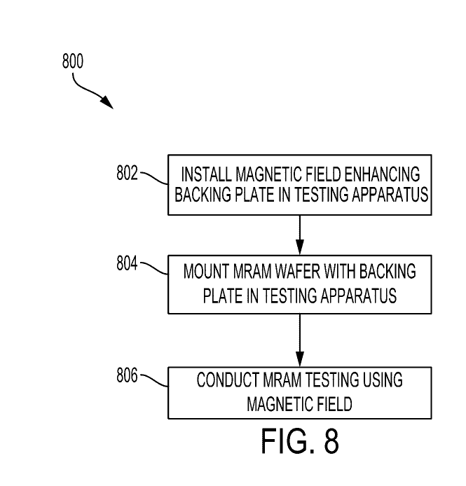

FIG. 8 is a flowchart of a method of testing a magnetic device, such as an MRAM, using a magnetic field enhancing backing plate during wafer testing. The method 800 begins when the magnetic field enhancing backing plate is installed in the test apparatus in step 802. The testing apparatus may be a probe testing apparatus such as the 300 mm probe station described above. The testing apparatus may accept wafers of varying sizes and is not limited to 300 mm probe stations. The device to be tested, typically an MRAM wafer, is installed with the magnetic field enhancing backing plate in step 804. MRAM testing is conducted using the magnetic field in step 806 and may consist of magnetic and electrical transport testing of the MRAM. The magnetic field applied to the MRAM may vary depending on the nature of the tests.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the exemplary embodiments disclosed herein may be implemented as electronic hardware, computer software, or combinations of both. To clearly illustrate this interchangeability of hardware and software, various illustrative components blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary embodiments of the invention.

The various illustrative logical blocks, modules, and circuits described in connection with the exemplary embodiments disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

In one or more exemplary embodiments, the functions described may be implemented in hardware, software, firmware, or any combination thereof If implemented in software, the functions may be stored on or transmitter over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM EEPROM, CD-ROM or other optical disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The previous description of the disclosed exemplary embodiments is provided to enable any person skilled in the art to make or use the invention. Various modifications to these exemplary embodiments will be readily apparent to those skilled in the art, and the generic principles defined herein may be applied to other embodiments without departing from the spirit or scope of the invention. Thus, the present invention is not intended to be limited to the exemplary embodiments shown herein but is to be accorded the widest scope consistent with the principles and novel features disclosed herein.

What is claimed is:

1. A method of testing a memory device, comprising:
installing a magnetic field enhancing backing plate in a test fixture;
installing a magnetic memory device in the test fixture;
applying a magnetic field to the magnetic memory device; and
determining performance of the magnetic memory device based on the applied magnetic field.

2. The method of claim 1, wherein the magnetic memory device is a wafer magnetic memory device.

3. The method of claim 1, wherein the magnetic field applied to the magnetic memory device is applied in-plane with the magnetic memory device.

4. The method of claim 1, wherein the magnetic field applied to the magnetic memory device is applied perpendicular to the magnetic memory device.

5. The method of claim 1, wherein the test fixture is a wafer test fixture.

6. The method of claim 1, wherein the magnetic field enhancing backing plate is applied near poles of a magnet in the test fixture.

7. An apparatus for testing a memory device, comprising:
a magnetic field enhancing backing plate adapted to a test fixture; and
a wafer test fixture.

8. The apparatus of claim 7, wherein the magnetic field enhancing backing plate is adapted to a wafer chuck in the wafer test fixture.

9. The apparatus of claim 7, wherein the magnetic field enhancing backing plate is formed from a high magnetic permeability material.

10. The apparatus of claim 9, wherein the high magnetic permeability material is low carbon steel.

11. The apparatus of claim 10, wherein the low carbon steel is 1006 low carbon steel.

12. The apparatus of claim 9, wherein the magnetic field enhancing backing plate is 1 mm thick.

13. The apparatus of claim 9, wherein the magnetic field enhancing backing plate is 5 mm thick.

14. An apparatus for testing a memory device, comprising:
means for installing a magnetic field enhancing backing plate in a test fixture;
means for installing a magnetic memory device in the test fixture;
means for applying a magnetic field to the magnetic memory device; and
means for determining performance of the magnetic memory device based on the applied magnetic field.

15. The apparatus of claim 14, wherein the means for installing a magnetic memory device in the test fixture installs a wafer magnetic memory to be tested.

16. The apparatus of claim 14, wherein the means for applying a magnetic field to the memory device applies the magnetic field in-plane with the magnetic memory device.

17. The apparatus of claim 14, wherein the means for applying a magnetic field to the memory device applied the magnetic field perpendicular to the magnetic memory device.
